(19) United States
(12) Patent Application Publication
(10) Pub. No.: US 2024/0142509 A1
(43) Pub. Date: May 2, 2024

(54) ONLINE MONITORING METHOD FOR DYNAMIC CHANGES IN POSITIONS OF TRANSMISSION LINE CONDUCTORS BASED ON ELECTROMAGNETIC SIGNALS OF GROUND WIRES

(71) Applicant: TSINGHUA UNIVERSITY, Beijing (CN)

(72) Inventors: Bo ZHANG, Beijing (CN); Zherui CUI, Beijing (CN); Zhecheng ZHANG, Beijing (CN); Jun HU, Beijing (CN); Jinliang HE, Beijing (CN)

(21) Appl. No.: 18/408,026

(22) Filed: Jan. 9, 2024

Related U.S. Application Data
(63) Continuation of application No. PCT/CN2022/092079, filed on May 10, 2022.

(30) Foreign Application Priority Data
Dec. 6, 2021 (CN) 202111477325.5
Dec. 6, 2021 (CN) 202111479145.0
Dec. 6, 2021 (CN) 202111511459.4
Dec. 6, 2021 (CN) 202111511460.7

(51) Int. Cl. G01R 31/08; G01R 31/58; H02J 3/00; H02J 13/00

(52) U.S. Cl. CPC G01R 31/085; G01R 31/58; H02J 3/0012; H02J 3/00125; H02J 13/00002; H02J 13/00032; H02J 13/0001

(57) ABSTRACT

An online monitoring method for dynamic changes in positions of transmission line conductors based on electromagnetic signals of ground wires and an apparatus are provided. The method includes: monitoring electromagnetic signals of ground wires; in response to changing in the electromagnetic signals, sending waveforms of the electromagnetic signals of the ground wires before and after changing to a data processing end; deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and obtaining dynamic changes in positions and movement statuses of the transmission line conductor based on the position change situations of the conductors.

### CROSS-REFERENCE TO RELATED APPLICATIONS

This application is a continuation of International Application No. PCT/CN2022/092079, filed on May 10, 2022, which claims priority to Chinese Patent Application Nos. 202111479145.0, 202111477325.5, 202111511459.4, and 202111511460.7, each filed on Dec. 6, 2021. The entire disclosures of the above-identified applications are incorporated herein by reference.

### TECHNICAL FIELD

The disclosure relates to the field of high voltage engineering technology, in particularly, to an online monitoring method for dynamic changes in positions of transmission line conductors based on electromagnetic signals of ground wires, and an apparatus thereof.

### BACKGROUND

A transmission line is the most failure prone part of a power system due to varied complex topography, complex climate conditions and human activities. A large portion of transmission line faults is related to changes in positions of conductors. Common reasons for the changes in positions of the conductors include conductor ice-over, conductor galloping, conductor offset caused by windage, as well as high conductor temperature caused by dynamic increase in transmission capacity of transmission line. Monitoring dynamic changes in positions of transmission line conductors can effectively provide early warnings of transmission line hidden dangers, which is significant to safety of the power grid.

### SUMMARY

In a first aspect, an embodiment of the present disclosure provides an online monitoring method for dynamic changes in positions of transmission line conductors based on electromagnetic signals of ground wires. The method includes: monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents; in response to changing in the electromagnetic signals, sending waveforms of the electromagnetic signals of the ground wires before and after changing to a data processing end, so as to determine change situations of the electromagnetic signals of the ground wires; deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and obtaining dynamic changes in positions and movement statuses of the transmission line conductors based on the position change situations of the conductors.

In a second aspect, the disclosure provides a non-transitory computer readable storage medium having a computer program stored thereon. When the computer program is executed by a processor, an online monitoring method for dynamic changes in positions of transmission line conductors based on electromagnetic signals of ground wires is implemented. The method includes: monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents; in response to changing in the electromagnetic signals, sending waveforms of the electromagnetic signals of the ground wires before and after changing to a data processing end, so as to determine change situations of the electromagnetic signals of the ground wires; deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and obtaining dynamic changes in positions and movement statuses of the transmission line conductors based on the position change situations of the conductors.

In a third aspect, an embodiment of the present disclosure provides an online monitoring apparatus for dynamic changes in positions of transmission line conductors based on electromagnetic signals of ground wires. The apparatus includes: a processor; and a memory, configured to store a computer program executable by the processor. When the computer program is executed by the processor, the processor is caused to execute: monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents; in response to changing in the electromagnetic signals, sending waveforms of the electromagnetic signals of the ground wires before and after changing to a data processing end, so as to determine change situations of the electromagnetic signals of the ground wires; deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and obtaining dynamic changes in positions and movement statuses of the transmission line conductors based on the position change situations of the conductors.

### BRIEF DESCRIPTION OF THE DRAWINGS

In order to more clearly illustrate the technical solution in the embodiments of the disclosure or the background technologies, the accompanying drawings that are required to be used in the embodiments of the disclosure or the background technologies are described below.

FIG. 1 is a flowchart illustrating an online monitoring method for dynamic changes in positions of transmission line conductors based on electromagnetic signals of ground wires proposed by an embodiment of the disclosure.

FIG. 2 is a schematic diagram illustrating a basic principle of monitoring dynamic changes in positions of conductors through electromagnetic signals of ground wires proposed by an embodiment of the disclosure.

FIG. 3 is a schematic diagram illustrating a monitoring solution for a ground wire connection method proposed by an embodiment of the disclosure.

FIG. 4 is a schematic diagram illustrating a method of calculating a conductor sag proposed by an embodiment of the disclosure.

FIG. 5 is a schematic diagram illustrating a relationship between a conductor sag and thickness of ice covering a conductor as well as a relationship between horizontal stress of a conductor with thickness of ice covering a conductor proposed by an embodiment of the disclosure.

FIG. 6 is a schematic diagram illustrating vertical position change situations of a conductor under different thickness of ice covering a conductor proposed by an embodiment of the disclosure.

FIG. 7 is a schematic diagram illustrating a relationship between a ground wire induced current and thickness of ice covering a conductor proposed by an embodiment of the disclosure.

FIG. 8 is a schematic diagram illustrating a sag monitoring method based on electromagnetic signals of ground wires in a case of dynamic increase in transmission capacity of transmission line proposed by an embodiment of the disclosure.

FIG. 9 is a schematic diagram illustrating an influence of a conductor sag in a ground wire induced current when monitoring conductor sag based on electromagnetic signals of ground wires in case of dynamic increase in transmission capacity of transmission line under different conductor currents proposed by an embodiment of the disclosure.

FIG. 10 is a schematic diagram illustrating an influence of a conductor sag in an induced potential of a ground wire insulator when monitoring conductor sag based on electromagnetic signals of ground wires in case of dynamic increase in transmission capacity of transmission line under different conductor currents proposed by an embodiment of the disclosure.

FIG. 11 is a schematic diagram illustrating a method for calculating a spatial position of a conductor in case of monitoring a conductor offset caused by windage proposed by an embodiment of the disclosure.

FIG. 12 is a schematic diagram illustrating a relationship between a ground wire induced current and a degree of a conductor offset caused by windage proposed by an embodiment of the disclosure.

FIG. 13 is a flowchart illustrating a method for monitoring conductor galloping of an overhead transmission line based on electromagnetic signals of ground wires proposed by an embodiment of the disclosure.

FIG. 14 is a schematic diagram illustrating an induced potential waveform on a segmented insulated ground wire during conductor galloping proposed by an embodiment of the disclosure.

FIG. 15 is a schematic diagram illustrating an induced current waveform on an OPGW that is grounded tower by tower during conductor galloping proposed by an embodiment of the disclosure.

FIG. 16 is a schematic diagram illustrating a relationship between an amplitude of galloping-related frequency component in a ground wire and an amplitude of conductor galloping proposed by an embodiment of the disclosure.

FIG. 17 is a schematic diagram illustrating a phase decrease law when galloping-related frequency component propagating along a ground wire by an embodiment of the disclosure.

FIG. 18 is a schematic diagram illustrating an amplitude decrease law when a galloping-related frequency component propagating along a ground wire proposed by an embodiment of the disclosure.

FIG. 19 is a schematic diagram illustrating a method of locating galloping spans for multi-span galloping situations proposed by an embodiment of the disclosure.

FIG. 20 is a schematic diagram illustrating an algorithm of locating a galloping span for an overhead transmission line based on electromagnetic signals of ground wires proposed by an embodiment of the disclosure.

### DETAILED DESCRIPTION

Embodiments of the disclosure are described in detail below, and examples of the embodiments are shown in the accompanying drawings, in which the same or similar numbers indicate the same or similar components or components having the same or similar function. The embodiments described below with reference to the accompanying drawings are exemplary and are intended only to explain the disclosure and are not to be used for limiting the disclosure.

A transmission line is the most failure prone part of a power system due to varied topography, complex climate conditions and human activities. A large portion of transmission line faults is related to positions of conductors. Common reasons for changes of conductor positions include conductor ice-over, conductor galloping, conductor offset caused by windage, as well as high conductor temperature caused by dynamic increase in transmission capacity of transmission line. Monitoring positions of transmission line conductors can effectively provide early warnings of transmission line hidden dangers, which is significant to safety of the power system.

The transmission line conductor ice-over mainly includes two types: rime and silver thaw. Generally, the rime is less dense and not tightly frozen. The silver thaw is dense and has strong adhesion capacity, and also tends to form ice covering around the conductor, which often causes excessive stress on the conductor, galloping, ice-shedding, thereby seriously affecting a normal operation of the transmission line. For example, ice disaster causes a large number of broken transmission lines and collapsed transmission towers. Therefore, a discussion on the issue of conductor ice-over mainly focuses on the situation of silver thaw.

The conductor offset caused by windage refers to a phenomenon that the transmission line conductor deviates from its original vertical position under the action of wind. The conductor offset caused by windage is different from the conductor galloping. When the wind speed is too large or too small, the conductor generally does not gallop. That is, the conductor galloping occurs only at a specific wind speed. For the conductor offset caused by windage, the greater the wind speed, the more serious the conductor offset phenomenon will be. The conductor offset caused by windage may result in a small distance between the conductors or between the conductor and a tower, and further result in flashover or a tripping fault. Due to the continuity of wind, reclosure generally cannot be successfully performed after the flashover or the tripping fault under the situation of conductor offset caused by windage, which may lead to transmission line outages, and bring great harm to the safe operation of the power system.

The conductor galloping, which is an abnormal movement state of the conductor, is mainly manifested as a vibration phenomenon with a low frequency and a large amplitude, accompanied by conductor twisting. The conductor galloping may cause great harm to the transmission line, for example, short-circuit fault due to line collision, wear and tear of conductor clamps, breakage of phase spacer, shedding of jump wire, loose and detaching of tower bolts, damage of tower frame. Therefore, conductor galloping will bring a huge challenge to safe and stable operation of the power system.

People's production and life demands for electricity are increasing as rapid development of economy and society. The capacities of some transmission lines are restricted by the existing transmission line technical specification. To solve this problem, relevant experts have proposed a solution of dynamic increase in transmission capacity of transmission line in order to improve an operating temperature of the conductor, which is 10-20° C. higher than the existing specification, and further increase the capacity of the transmission line. However, as the conductor temperature rises, the conductor will expansion and the conductor sag will increase. An excessive conductor sag may endanger the normal operation of the transmission line and affect safety of surrounding things.

For the above problems that influence the safe operation of the transmission line, there are some corresponding online monitoring attempts. But the related solutions cannot satisfy the requirements for online monitoring dynamic changes in positions of transmission line conductors due to low accuracy, high cost, difficult installation and maintenance. The specific disadvantages are listed as follows. Firstly, the effect of non-contact optical monitoring devices which are mainly based on video monitoring is limited by the small visible range and unclear images under adverse weather conditions. Secondly, online monitoring devices which are directly in contact with the conductors need to be installed in the middle of the span during interruption maintenance or through hot-line working, and are prone to wear and tear, resulting in difficulties in the device installation and maintenance. Thirdly, existing technical solutions need to install a plurality of sensors in each span to achieve effective conductor position monitoring, resulting in a high cost of monitoring data communication and processing.

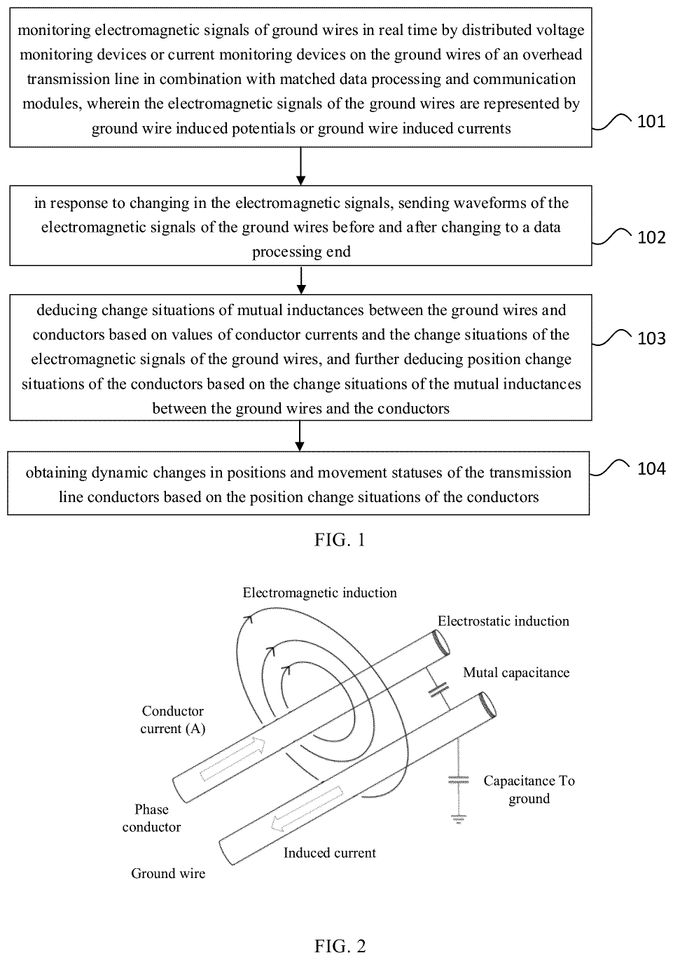

There are power-frequency currents in the conductors of an AC (alternating current) transmission line, which can produce a changing magnetic field in the space. When the changing magnetic field acts on a ground wire loop, which is formed by “ground wire-earth” or two ground wires, there will be induced potential in the ground wire loop. The induced potential further generates the induced potential of a ground wire insulator or the induced current in the ground wire. The basic principle of this phenomenon is Faraday's law of electromagnetic induction, as shown in FIG. 2, which is expressed as follows:

$$\\ \{ \begin{matrix}{\int }_{l} B \cdot dl = μ {\sum }_{k = 1}^{n} {I}_{k} \\ ε = - n \frac{Δ ϕ}{Δ t}\end{matrix}$$

Taking this law as the theoretical basic, the present disclosure performs an online monitoring method for dynamic changes in positions and movement statuses of transmission line conductors based on electromagnetic signals of ground wires. Ground wire induced potentials or ground wire induced currents are closely related to relative positions between the conductors and the ground wires as well as conductor currents.

Embodiments of the disclosure provide an online monitoring method for dynamic changes in positions of transmission line conductors based on electromagnetic signals of ground wires and a corresponding apparatus, which can online monitor dynamic changes in positions of conductors under situations such as conductor galloping, conductor ice-over, conductor offset caused by windage, and conductor sag change in a case of dynamic increase in transmission capacity of transmission line. Through online monitoring the dynamic changes in positions of the transmission line conductors, hidden dangers of the transmission line can be rapidly recognized and located, which is of great significance for improving safety, reliability and stability of a power system.

An online monitoring method for dynamic changes in positions of transmission line conductors based on electromagnetic signals of ground wires and an online monitoring apparatus for dynamic changes in positions of transmission line conductors based on electromagnetic signals of ground wires are described below with reference to the accompanying drawings.

FIG. 1 is a flowchart illustrating an online monitoring method for dynamic changes in positions of transmission line conductors based on electromagnetic signals of ground wires proposed by an embodiment of the disclosure.

As shown in FIG. 1, the method includes the following steps.

At step 101, ground wire induced potentials or induced currents are monitored in real time by distributed voltage monitoring devices or current monitoring devices on the ground wires of an overhead transmission line in combination with matched data processing and communication modules.

It is noted that the electromagnetic signals of the ground wires are represented by the ground wire induced potentials or the ground wire induced currents. Monitoring the potentials or monitoring the currents depends on a connection method between a ground wire and a tower.

At step 102, in response to changing in the ground wire induced potentials or the ground wire induced currents, after determined by a relevant module, waveforms of the ground wire induced potentials or the ground wire induced currents before and after changing are sent to a data processing end.

At step 103, change situations of mutual inductances between the ground wires and conductors are deduced based on values of conductor currents and change situations of the acquired electromagnetic signals of the ground wires. Then position change situations of the conductors are obtained based on the change situations of the mutual inductances between the ground wires and the conductors.

At step 104, dynamic changes in positions and movement statuses of the transmission line conductors are online monitored based on the position change situations of the conductors.

According to the method in embodiments of the present disclosure, the ground wire induced potentials or the ground wire induced currents are monitored in real time by the distributed voltage monitoring devices or current monitoring devices on the ground wires of the overhead transmission line in combination with the matched data processing and communication modules. In response to changing in the ground wire induced potentials or the ground wire induced currents, the waveforms of the ground wire induced potentials or the ground wire induced currents before and after changing are sent to the data processing end. The change situations of the mutual inductances between the ground wires and the conductors are obtained based on the values of the conductor currents and the change situations of the acquired electromagnetic signals of the ground wires, and the position change situations of the conductors are obtained based on the change situations of the mutual inductances between the ground wires and the conductors. The dynamic changes in positions and the movement statuses of the transmission line conductors are online monitored based on the position change situations of the conductors. Therefore, the problems of large number of sensors, unsatisfactory monitoring effect, high cost, difficult installation and maintenance in the existing methods may be solved. Additionally, the problem of affecting normal operation of the transmission line in case of sensor failures in the existing methods may also be solved. Meanwhile, the method provided in the present disclosure can realize self-powered online monitoring of the conductor position information without additional power supply because the amplitudes of ground wire potential and current are stable and relatively large. The present disclosure provides the online monitoring method for the dynamic changes in positions of the overhead transmission line conductors based on induced potentials of segmented insulated ground wire insulators or induced currents of an optical fiber composite overhead ground wire (OPGW) that is grounded tower by tower, which has advantages of simple principle, low cost, easy installation and maintenance, and high feasibility.

Further, in an embodiment of the disclosure, the position change situation of each conductor includes at least one of: a conductor sag change situation, a conductor galloping situation and a conductor offset situation caused by windage.

Furthermore, in an embodiment of the disclosure, a cause of the conductor sag change situation includes at least one of: dynamic increase in transmission capacity of transmission line and conductor ice-over.

In an embodiment of the disclosure, the method further includes: supplying power to the monitoring devices through the ground wire induced potentials or the ground wire induced currents to achieve self-power.

In an embodiment of the disclosure, when the cause of the conductor sag change situation is the dynamic increase in transmission capacity of transmission line or the conductor ice-over, online monitoring the conductor sag change situation includes: analyzing and determining the change situations of the mutual inductances between the ground wires and the conductors based on change situations of the conductor currents and the change situations of the ground wire induced potentials or the ground wire induced currents; obtaining change situations of distances between the ground wires and the conductors based on the change situations of the mutual inductances between the ground wires and the conductors; further refining and obtaining the conductor sag change situation based on the change situations of the distances between the ground wires and the conductors; and generating an alarm in response to determining that a conductor sag being greater than a preset sag threshold based on the conductor sag change situation.

In an embodiment of the disclosure, when the cause of the conductor sag change situation is the conductor ice-over, the online monitoring method further includes: on the basic of considering conductor deformation, obtaining a relationship between horizontal stress and thickness of ice covering a conductor and a relationship between a conductor sag and thickness of ice covering a conductor by analyzing an influence of an ice gravity in a ratio of a conductor load per unit length to a conductor cross-sectional area, the horizontal stress of the conductor, and the conductor sag. The thickness of the ice covering the conductor may be determined based on the monitored conductor sag and the relationship between the conductor sag and the thickness of the ice covering the conductor, and then the horizontal stress of the conductor covered by ice may be determined based on the thickness of the ice covering the conductor and the relationship between the horizontal stress and the thickness of ice covering the conductor.

Furthermore, in an embodiment of the disclosure, online monitoring the conductor offset situation caused by windage includes: analyzing and determining the change situations of the mutual inductances between the ground wires and the conductors based on the conductor currents and the change situations of the monitored ground wire induced potentials or the ground wire induced currents; obtaining change situations of distances between the ground wires and the conductors based on the change situations of the mutual inductances between the ground wires and the conductors; further refining and obtaining a spatial position change situation of each conductor based on the change situations of the distances between the ground wires and the conductors; obtaining the conductor offset situation caused by windage based on the spatial position change situation of the conductor; and generating an alarm in response to determining that a conductor offset being greater than a preset offset threshold based on the conductor offset situation caused by windage.

In an embodiment of the disclosure, the method further includes: online monitoring and locating the conductor galloping situation. Online monitoring and locating the conductor galloping situation includes:
step S1: obtaining relevant parameters of the overhead transmission line and establishing an equivalent circuit of the ground wires based on the relevant parameters;
step S2: monitoring the electromagnetic signals of the ground wires in real time and performing spectrum analysis on the monitored electromagnetic signals;
step S3: in response to detecting an abnormal frequency component in the spectrum analysis, sending waveforms of the monitored electromagnetic signals of the ground wires to the data processing end and generating an analysis result, in which, the monitored electromagnetic signals of the ground wires may include the ground wire induced potentials or the ground wire induced currents;
step S4: determining a frequency, a position and an amplitude of conductor galloping based on the analysis result;
step S5: executing steps S2, S3, and S4 repeatedly and continuously, and generating an alarm in response to the amplitude of conductor galloping being greater than a preset amplitude threshold.

In this technical solution, the equivalent circuits of the ground wires are established by obtaining the relevant parameters of the overhead transmission line, and the ground wire induced currents or the ground wire induced potentials are further monitored in real time, and the spectrum analysis is performed on the monitored ground wire induced currents or ground wire induced potentials. Thus, monitoring the conductor galloping may be achieved. There is no need to install the monitoring devices span by span based on the proposed method in the disclosure, so the cost of monitoring and locating conductor galloping are greatly reduced.

Furthermore, in an embodiment of the disclosure, determining the frequency, the position and the amplitude of conductor galloping based on the analysis result includes:
determining the frequency of the conductor galloping;
obtaining phase information of a galloping-related frequency component based on the frequency of the conductor galloping;
determining the position of the conductor galloping based on the phase information of the galloping-related frequency component; and
calculating the amplitude of the conductor galloping based on the position of the conductor galloping and the monitored electromagnetic signals of the ground wires.

More specifically, determining the frequency, the position and the amplitude of conductor galloping based on the analysis result includes:
determining the frequency of the conductor galloping by performing the spectrum analysis on the monitored electromagnetic signals of the ground wires;
obtaining the phase information of the galloping-related frequency component in the monitored electromagnetic signals of the ground wires;
determining the position of the conductor galloping based on the phase information of the galloping-related frequency component monitored by the distributed monitoring devices and a phase distribution law of the galloping-related frequency component along the transmission line; and
calculating the amplitude of the conductor galloping based on the position of the conductor galloping and amplitudes of the galloping-related frequency component monitored by the distributed monitoring devices, an amplitude distribution law of the galloping-related frequency component along the transmission line, and a relationship between the amplitude of the conductor galloping and the amplitude of the galloping-related frequency component.

For example, the phase distribution law and the amplitude distribution law, and the relationship between the amplitude of the conductor galloping and the amplitude of the galloping-related frequency component may be obtained through simulation before the electromagnetic signals are monitored.

### Implementation 1

The following introduction is made in detail on the online monitoring method for the dynamic changes in positions of transmission line conductors based on electromagnetic signals of ground wires provided by the present disclosure by taking monitoring conductor ice-over of an overhead transmission line based on the electromagnetic signals of the ground wires as an example.

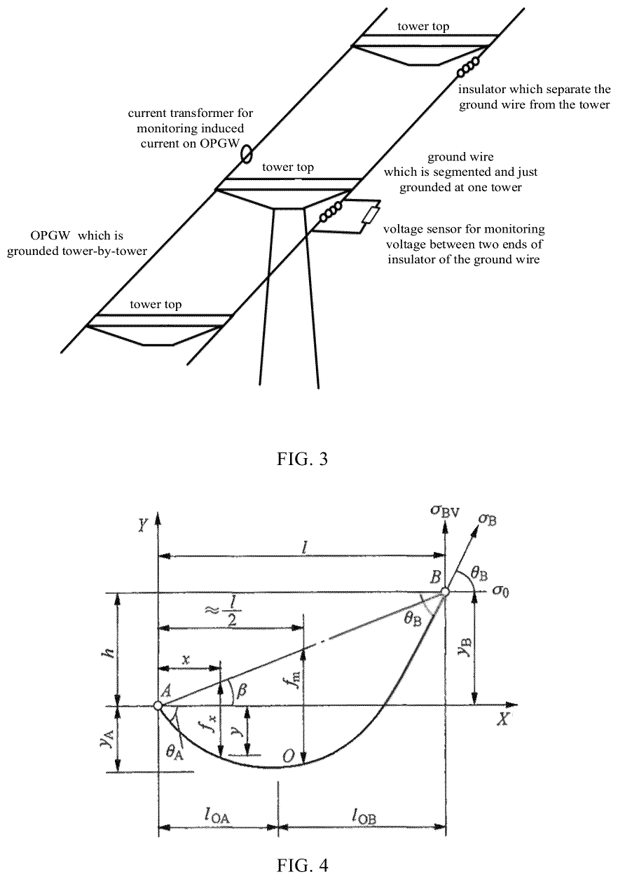

When the conductor is covered with ice, the conductor sag will increase due to an ice gravity and lead to changes of distances between the ground wires and the conductors. Then the mutual inductances between the conductors and the ground wires changes. The ground wire induced potentials and the ground wire induced currents will also change accordingly when the conductor currents are fixed. Moreover, the thicker the ice covering the conductor, the greater the changes of the electromagnetic signals of the ground wires. Therefore, the situation of conductor ice-over may be online monitored based on the electromagnetic signals of the ground wires, as shown in FIG. 3.

According to the above contents, this embodiment analyzes and determines the change situations of the mutual inductances between the ground wires and the conductors based on the conductor currents and the change situations of the ground wire induced potentials or the ground wire induced currents, and then obtains the change situations of the distances between the ground wires and the conductors, and further obtains and refines the conductor sag change situation based on the change situations of the distances between the ground wires and the conductors, and finally obtains the thickness of ice covering the conductor based on the conductor sag change situation.

The change situations of the mutual inductances between the ground wires and the conductors are obtained based on the conductor currents and the change situations of the electromagnetic signals of the ground wires, which can be expressed by a first formula:

E_{G}=Z_{GL}I_{L},

where E_{G} denotes potential drops per unit length on the ground wires, Z_{GL} denotes mutual impedances per unit length between the conductors and the ground wires, and I_{L} denotes power-frequency currents in the conductors. E_{G} may be represented by the ground wire induced potentials or currents. Then, changes of E_{G} may be obtained when changes of the ground wire induced potentials or currents are monitored.

The change situation of the distance between the conductor and the ground wire is obtained based on the change situation of the mutual inductance between the conductor and the ground wire, which can be expressed by a second formula:

$$\\ {Z}_{ij} = 0.05 + j ω \cdot 2 \times {10}^{- 4} \times ln \frac{{D}_{g}}{{d}_{ij}} ( Ω / km ) ,$$

where Zᵢⱼ denotes a mutual impedance between the i^{th} conductor and the j^{th} ground wire, ω=2πf, f denotes a power-frequency (Hz), dᵢⱼ denotes a distance between the i^{th} conductor and the j^{th} ground wire. D_{g} denotes a mirror equivalent depth of the j^{th} ground wire relative to the ground, with a unit of meter (m), which can be calculated as

$$\\ {D}_{g} = 660 \sqrt{\frac{ρ}{f}} ,$$

where ρ denotes a soil resistivity of the ground (Ω·m), and f denotes a power-frequency (Hz).

The conductor sag change situation is obtained based on the change situations of the distances between the ground wires and the conductors. When calculating the conductor sag, a catenary model of the conductor is applied. For calculation simplicity, a catenary formula is replaced by a horizontal parabola formula. When taking a suspension point at one end of the conductor as an origin point, as shown in FIG. 4, a third formula is expressed as:

$$y = x tan β - \frac{γ x ( l - x )}{2 {σ}_{0}} ,$$

where, y denotes a vertical position of the conductor at position x, β denotes a height difference angle of two suspension points of the conductor, in which

$$tan β = \frac{h}{l} ;$$

and h denotes a height difference between two suspension points of the conductor, l denotes a length of a span, γ denotes a ratio of a conductor load per unit length to a cross-sectional area of the conductor, with a unit of N/(m·mm²), σ₀ denotes horizontal stress at each point of the conductor, with a unit of N/mm².

Obtaining the thickness of the ice covering the conductor based on the conductor sag change situation includes:
on the basic of considering the conductor deformation, obtaining a relationship between

horizontal stress and thickness of ice covering a conductor, and a relationship between a conductor sag and thickness of ice covering a conductor by analyzing an influence of an ice gravity in a ratio of a conductor load per unit length to a conductor cross-sectional area.

Without considering an influence of wind, the ratio of the conductor load per unit length to the conductor cross-sectional area is calculated when the conductor is covered with ice, which can be expressed by a fourth formula:

$$γ = \frac{9.8 \times {ρ}_{1} + 9.8 \times 0.9 πδ ( δ + d ) \times {10}^{- 3}}{A} ,$$

where, ρ₁ denotes a conductor self-load per unit length, with a unit of kg/m; δ denotes the thickness of the ice covering the conductor, with a unit of mm; d denotes the diameter of the conductor, with a unit of mm; A denotes the conductor cross-sectional area, with a unit of mm².

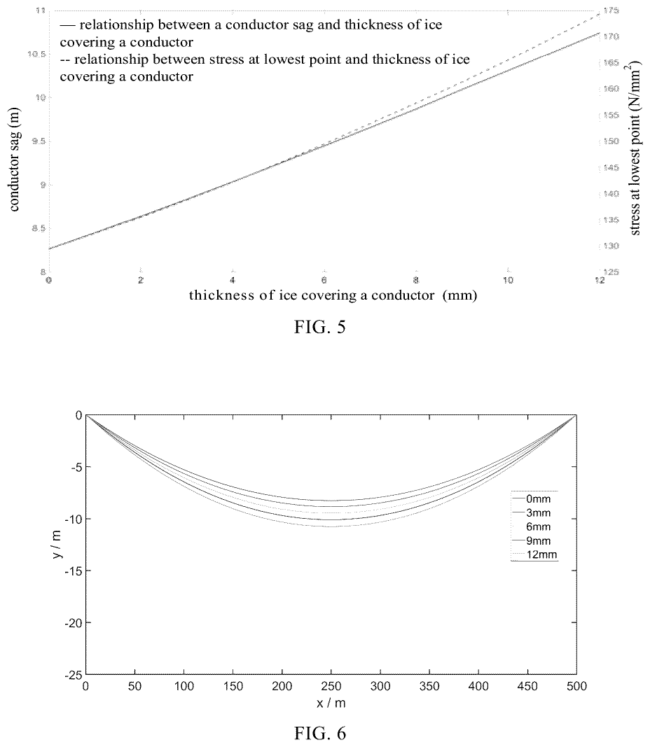

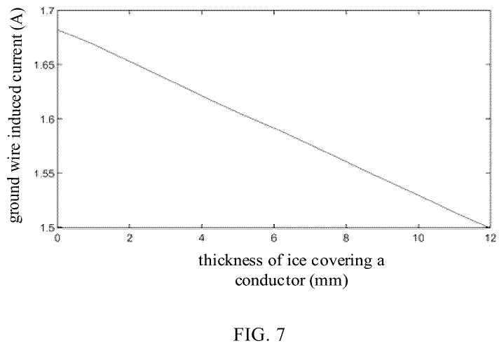

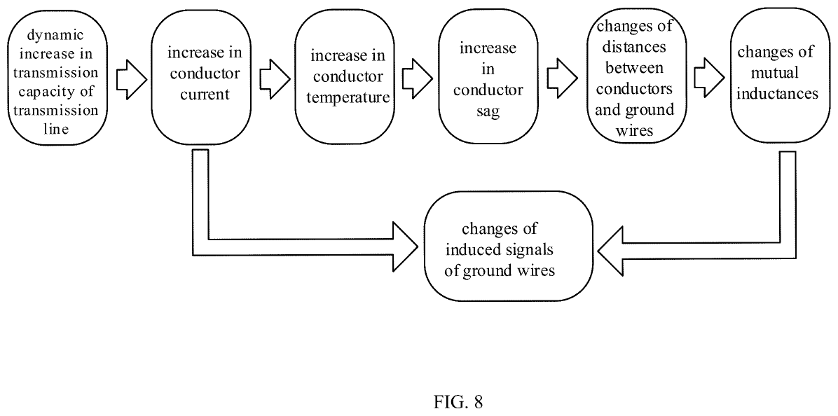

More specifically, during the calculation process, in order to describe an effect of the method more visually, the height difference between the suspension points at two ends of the conductor is set as zero. The method is still feasible when the heights of the conductor suspension points are different. The span of the conductor is set as 500 m, conductors are selected as quad bundle JLHA1/GA1-400/95, and specific parameters of the conductors are shown in Table 1. The calculation also uses the relevant simulation software to consider the conductor deformation caused by ice and temperature. Based on the above considerations, the relationship between the conductor sag and the thickness of ice covering the conductor as well as the relationship between the horizontal stress at each point of the conductor and the thickness of ice covering the conductor can be obtained, as shown in FIG. 5. The relationship between the conductor sag and the thickness of ice covering the conductor can be further obtained, as shown in FIG. 6. It can be seen from the calculation result that the conductor sag and the horizontal stress of the conductor increase approximately linearly with the increase of the thickness of ice covering the conductor. After obtaining the relationship between the conductor sag and the thickness of ice covering the conductor, the change rule of the ground wire induced currents with the thickness of ice covering the conductor can be obtained in combination with the relevant deduction and calculation, as shown in FIG. 7. The connection method of the ground wires in the illustration is that the normal ground wire is segmented insulated and the OPGW is grounded tower by tower.

TABLE 1

| Parameter name | Parameter value |
|---|---|
| external diameter (mm) | 29.1 |
| specific weight (kg/km) | 1856.7 |
| spring coefficient (N/mm\hat{ }2) | 78000 |
| linear expansion coefficient (1/° C.*1E−6) | 18 |

After the relationship between the ground wire induced current and the thickness of ice covering the conductor is obtained, in subsequent practical applications, the thickness of ice covering the conductor can be inversely deduced based on the monitored ground wire induced currents in combination with the parameters of the conductor. The monitoring method and effect based on the ground wire induced potentials are similar to those based on the ground wire induced currents.

### Implementation 2

The following introduction is made in detail on the online monitoring method for the dynamic changes in positions of transmission line conductors based on electromagnetic signals of ground wires provided by the present disclosure by taking sag monitoring in case of dynamic increase in transmission capacity of transmission line as an example.

When the transmission line capacity increases, the conductor sag changes due to heat expansion, which leads to the changes of the distances between the conductors and the ground wires. Therefore, the mutual inductances between the conductors and the ground wires change. Consequently, the ground wire induced potentials or the ground wire induced currents will not only change with the conductor currents, but also change with the conductor sags. Therefore, after obtaining information of the conductor currents, the conductor sag change situation in a case of dynamic increase in transmission capacity of transmission line can be online monitored based on the electromagnetic signals of the ground wires. The schematic diagram of the specific process is shown in FIG. 8.

The change situations of mutual inductances between the ground wires and the conductors can be obtained based on the values of the conductor currents and the change situations of the acquired electromagnetic signals of the ground wires. Further, the position change situation of each conductor can be calculated through the change situations of the mutual inductances between the ground wires and the conductors. The contents above include:
analyzing and determining the change situations of the mutual inductances between the ground wires and the conductors by comprehensively considering the change situations of the conductor currents and the change situations of the monitored ground wire currents or ground wire potentials in a case of dynamic increase in transmission capacity of transmission line, which can be obtained according to a fifth formula. The fifth formula is expressed as:

E_{G}=Z_{GL}I_{L},

where E_{G} denotes potential drops per unit length on the ground wires, Z_{GL} denotes mutual impedances between the conductors and the ground wires, and I_{L} denotes power-frequency currents in the conductors. E_{G} may be represented by the ground wire induced potentials or currents. Then, changes of E_{G} may be obtained when changes of the ground wire induced potentials or currents are monitored.

Taking a single-circuit transmission line with two ground wires as an example, the fifth formula can also be expressed as:

$$[ \begin{matrix}{E}_{g 1} \\ {E}_{g 2}\end{matrix} ] = [ \begin{matrix}{Z}_{g 1 a} & {Z}_{g 1 b} & {Z}_{g 1 c} \\ {Z}_{g 2 a} & {Z}_{g 2 b} & {Z}_{g 2 c}\end{matrix} ] [ \begin{matrix}{I}_{a} \\ {I}_{b} \\ {I}_{c}\end{matrix} ] ,$$

where, E_{g1} denotes a potential drop per unit length on a first ground wire, E_{g2} denotes a potential drop per unit length on a second ground wire, Z_{g1a} denotes a mutual impedance between the first ground wire and a phase a conductor, Z_{g1b} denotes a mutual impedance between the first ground wire and a phase b conductor, Z_{g1c} denotes a mutual impedance between the first ground wire and a phase c conductor, similarly, Z_{g2a} denotes a mutual impedance between the second ground wire and the phase a conductor, Z_{g2b} denotes a mutual impedance between the second ground wire and a phase b conductor, Z_{g2c} denotes a mutual impedance between the second ground wire and a phase c conductor. Iₐ denotes a current of the phase a conductor, I_{b} denotes a current of the phase b conductor, and I_{c} denotes a current of the phase c conductor.

The change situation of the distance between the conductor and the ground wire can be obtained based on the change situation of the mutual inductance between the conductor and the ground wire according to a sixth formula, which is expressed as:

$${Z}_{ij} = 0.05 + j ω \cdot 2 \times {10}^{- 4} \times ln \frac{{D}_{g}}{{d}_{ij}} ( Ω / km ) ,$$

where Zᵢⱼ denotes a mutual impedance between the i^{th} conductor and the j^{th} ground wire, ω=2πf, f denotes a power-frequency (Hz), dᵢⱼ denotes a distance between the i^{th} conductor and the j^{th} ground wire, D_{g} denotes a mirror equivalent depth of the j^{th} ground wire relative to the ground, with a unit of m, which can be calculated as

$${D}_{g} = 660 \sqrt{\frac{ρ}{f}} ,$$

where ρ denotes a soil resistivity of the ground (Ω·m), and f denotes a power-frequency (Hz).

The mutual impedances can be calculated based on a value of the mutual inductance: Zᵢⱼ=0.05+jω·Lᵢⱼ. In order to obtain more accurate position information of each point of the conductor, the mutual inductances between the conductors and the ground wires can be calculated by numerical integration in the simulation. The conductors and the ground wires are divided into n segments along the span. Taking the mutual impedance between the phase a conductor and the first ground wire as an example, the mutual impedance between the phase a conductor and the first ground wire can be obtained by accumulating the mutual impedance between each conductor segment and each ground wire segment, which can be expressed as:

$${Z}_{g 1 a} = 0.05 + j ω \frac{2 \times 1 {0}^{- 4}}{n} {\sum }_{k = 0}^{n} ln \frac{{D}_{g}}{{d}_{g 1 a} ( k )} ( Ω / km ) ,$$

where Z_{g1a} denotes the mutual impedance between the first ground wire and the phase a conductor, ω=2πf, f denotes a power-frequency (Hz), and d_{g1a}(k) denotes a distance between the k^{th} segment of the phase a conductor and the k^{th} segment of the first ground wire.

The conductor sag change situation may be obtained based on the change situations of the distances between the ground wires and the conductors according to a seventh formula, which is expressed as:

$$y = x tan β - \frac{γ x ( l - x )}{2 {σ}_{0}} ,$$

where, y denotes a vertical position of the conductor at position x, β denotes a height difference angle of two suspension points of the conductor, in which

$$tan β = \frac{h}{l} ,$$

h denotes a height difference between two suspension points of the conductor, l denotes a length of a span, γ denotes a ratio of a conductor load per unit length to a conductor cross-sectional area, with a unit of N/(m·mm²), σ₀ denotes horizontal stress at each point of the conductor, with a unit of N/mm².

FIG. 4 is a schematic diagram illustrating a conductor sag. The symbol y in FIG. 4 corresponds to y in the seventh formula, which represents the vertical position of the conductor at a horizontal position x within the span. In FIG. 4, A and B denote suspension points at two ends of the conductor, O denotes a lowest point of the catenary model of the conductor, h denotes a height difference between two suspension points of the conductor, l denotes a horizontal distance between two suspension points of the conductor, i.e., the length of the span, and fₘ denotes the conductor sag.

For a certain span of transmission line under normal circumstances, the suspension points at two ends of each conductor and each ground wire are fixed. Therefore, the positions of each conductor and each ground wire in the vertical direction can be calculated by the seventh formula (γ and σ₀ denote two known parameters respectively for the certain span of transmission line under normal circumstances). Although sags of the conductors and the ground wires are different, relative positions of them are fixed.

During dynamic increase in transmission capacity of transmission line, the conductor current increases. Therefore, the conductor temperature increases, leading to the expansion of conductor length. Correspondingly, the two parameters of γ and σ₀ in the seventh formula change, which results in the change of conductor sags. The disclosure obtains the change situations of the distances between the ground wires and the conductors based on the change situations of the monitored ground wire induced potentials or ground wire induced currents. Since the vertical positions of the ground wires are fixed and are calculated according to the seventh formula, the positions of the conductors can be obtained.

Original vertical positions of the conductors and original vertical positions of the ground wires can be calculated by the seventh formula, and then the vertical positions of the conductors after the transmission capacity increases can be obtained based on the original vertical positions of the conductors and the changes of the distances between the conductors and the ground wires. Then the conductor sag change situation can be obtained.

In an embodiment of the disclosure, during the calculation process, in order to describe an effect of the method more visually, the height difference between the suspension points at two ends of the conductor is set as zero. The method is still feasible when the heights of the conductor suspension points are different. The span of the conductor is set as 500 m. Conductors are selected as quad bundle JLHA1/GA1-400/95. The specific parameters of the conductors are shown in Table 1.

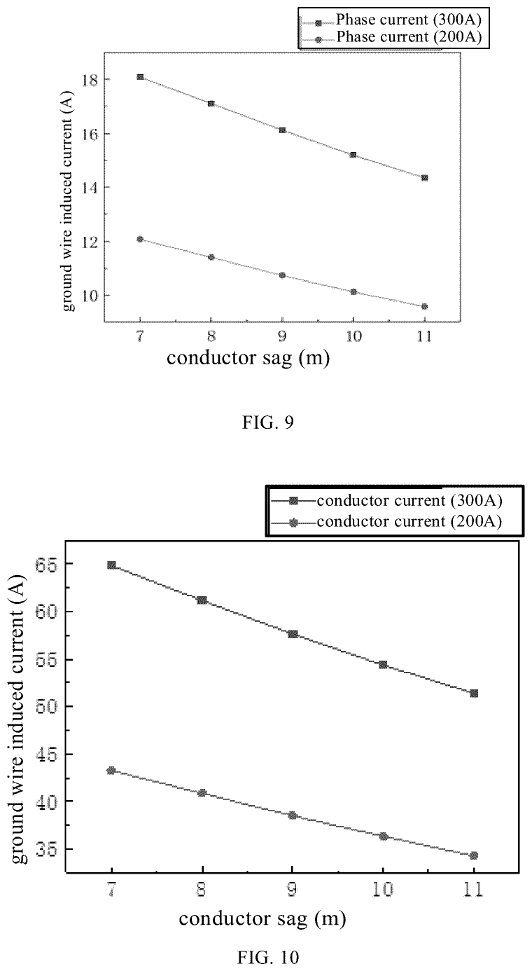

FIG. 9 is a schematic diagram illustrating an influence of a conductor sag in a ground wire induced current when monitoring conductor sag based on electromagnetic signals of ground wires in a case of dynamic increase in transmission capacity of transmission line under different conductor currents.

The connection method of the ground wires corresponding to FIG. 9 is that the two ground wires are grounded tower by tower. When the conductor current is constant, an amplitude of the ground wire induced current decreases approximately linearly with the increasing of the conductor sag. On the basic of this law, the conductor sag change situation may be obtained according to the change situations of the ground wire induced currents and the change situations of the conductor currents.

FIG. 10 is a schematic diagram illustrating an influence of a conductor sag in an induced potential of a ground wire insulator when monitoring conductor sag based on electromagnetic signals of ground wires in a case of dynamic increase in transmission capacity of transmission line under different conductor currents according to an embodiment of the disclosure.

The connection method of the ground wires corresponding to FIG. 10 is that the normal ground wire is segmented insulation to the tower and the OPGW is grounded tower by tower. When the conductor current is constant, an amplitude of the ground wire induced potential decreases approximately linearly with the increasing of the conductor sag. On the basic of this law, the conductor sag change situation may be obtained according to the change situations of the ground wire induced potentials and the change situations of the conductor currents.

After obtaining the relationship between the ground wire induced current and the conductor sag under different conductor currents or the relationship between the ground wire induced potential and the conductor sag under different conductor currents, the conductor sag change situation can be inversely deduced based on the monitored electromagnetic signals of the ground wires in a subsequent practical application.

### Implementation 3

The following introduction is made in detail on an online monitoring method for the dynamic changes in positions of transmission line conductors based on electromagnetic signals of ground wires provided by the present disclosure. The situation of monitoring the conductor offset caused by windage is taken as an example.

When the conductor offset situation caused by windage occurs, the position of each conductor changes with their suspension points as axes and with sags as radii. Therefore, the distances between the conductors and the ground wires change, resulting in the changes of mutual inductances between the conductors and the ground wires. The ground wire induced potentials and the ground wire induced currents will also change accordingly when the conductor currents are constant. The larger the conductor offset caused by windage, the greater the changing in the electromagnetic signals of the ground wires. Therefore, the conductor offset situation caused by windage can be online monitored based on the electromagnetic signals of the ground wires, as shown in FIG. 3.

As the contents above, in this embodiment, the change situations of the mutual inductances between the ground wires and the conductors are analyzed and determined based on the change situations of the monitored ground wire induced potentials or ground wire induced currents. Further, the change situations of the distances between the ground wires and the conductors are obtained, and then the spatial position change situation of each conductor is obtained based on the change situations of the distances between the ground wires and the conductors. Finally, the conductor offset situation caused by windage can be obtained based on the spatial position change situation of the conductor. An alarm will be generated in response to determining that the conductor offset exceeds the preset offset threshold.

The change situations of the mutual inductances between the ground wires and the conductors are obtained based on the conductor currents and the change situations of the electromagnetic signals of the ground wires, which can be expressed by an eighth formula:

E_{G}=Z_{GL}I_{L},

where E_{G} denotes potential drops per unit length on the ground wires, Z_{GL} denotes mutual impedances per unit length between the conductors and the ground wires, and I_{L} denotes power-frequency currents in the conductors. E_{G} may be represented by the ground wire induced potentials or currents. Then, changes of E_{G} may be obtained when changes of the ground wire induced potentials or currents are monitored.

The change situation of the distance between the conductor and the ground wire is obtained based on the change situation of the mutual inductance between the conductor and the ground wire, which can be expressed by a ninth formula:

$${Z}_{ij} = 0.05 + j ω \cdot 2 \times {10}^{- 4} \times ln \frac{{D}_{g}}{{d}_{ij}} ( Ω / km ) ,$$

where Zᵢⱼ denotes a mutual impedance between the i^{th} conductor and the j^{th} ground wire, ω=2πf, f denotes a power-frequency (Hz), dᵢⱼ denotes a distance between the i^{th} conductor and the j^{th} ground wire, D_{g} denotes a mirror equivalent depth of the j^{th} ground wire relative to the ground, with a unit of meter (m), which can be calculated as

$${D}_{g} = 660 \sqrt{\frac{ρ}{f}} ,$$

where ρ denotes a soil resistivity of the ground (Ω·m), and f denotes a power-frequency (Hz).

When analyzing the change of the distance between the conductor and the ground wire caused by windage, a catenary model is applied. Since a distance between two suspension points of the conductor is large, the rigidity has little influence in the shape of the suspended conductor. A tenth equation for calculating the position of the conductor is expressed as:

$$y = \frac{T}{q} cosh ( \frac{q}{T} ( x - {x}_{0} ) ) + {y}_{0} ,$$

where y denotes a vertical position of the conductor at a position x, q denotes a per unit load of the conductor, T denotes a tension of the conductor; x₀ and y₀ describe relative positions of the conductor, which can determine origin points of calculation.

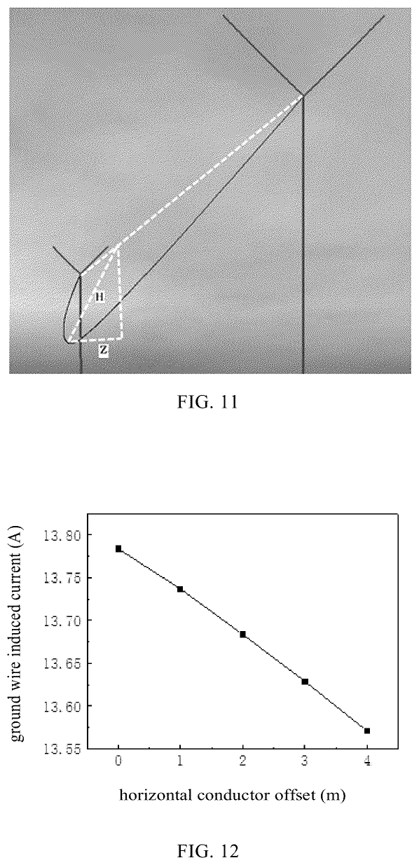

When the conductor offset situation caused by windage occurs, the conductor can no longer be represented by the form of catenary equation in the vertical plane. Therefore, an “off-angle catenary” model is applied, which represents the conductor deviating a certain distance along the longitudinal direction, as shown in FIG. 11.

In this case, a parameter z is introduced to describe the horizontal offset at the lowest point of the conductor. When z is a positive number, it indicates that the conductor is offset outward, and when z is a negative number, it indicates that the conductor is offset inward. It is assumed that a wind-force acting on each point of the conductor is uniform or not significantly different. Then the relationship between the conductor horizontal offset and the longitudinal offset can be described by the white right triangle in FIG. 11.

Based on the contents above, the position of the conductor in the span can be determined by two parameters a and z, which is expressed as:

$$y = [ \frac{L}{a} cosh ( \frac{a}{L} x - \frac{a}{2} ) - \frac{L}{a} cosh ( \frac{a}{2} ) ] sin α ,$$

where,

$$α = arccos ( \frac{z}{H} ) and H = \frac{L}{a} ( cosh ( \frac{a}{2} ) - 1 ) , y$$

denotes a vertical position of the conductor at a position x, z and H correspond to reference marks z and H in FIG. 11. L denotes a length of a span, a denotes a sag-related parameter, which is defined as:

$$\frac{T}{q} = \frac{L}{a} , q$$

denotes a per unit load of the conductor, T denotes a tension of the conductor.

More specifically, during the calculation process, in order to describe an effect of the method more visually, the height difference between the suspension points at two ends of the conductor is set as zero. The method is still feasible when the heights of the suspension points are different. The span of the transmission line is set as 500 m. Conductors are selected as quad bundle JLHA1/GA1-400/95. The specific parameters of the conductors are shown in Table 1. The offset distance of the conductor relative to its original position without wind is used to represent a degree of windage yaw, i.e., the value z in FIG. 11. The ground wire connection method in this example is that normal ground wire is segmented insulated and OPGW is grounded tower by tower. The influence of the value of z in the ground wire induced current is shown in FIG. 12 (the conductor sag is fixed as 16 m). It can be seen from the result that the value of the ground wire induced current is approximately proportional to the conductor horizontal offset during the conductor offset caused by windage.

After obtaining the relationship between the ground wire induced current and the horizontal offset during the conductor offset caused by windage, in subsequent practical applications, the degree of the conductor offset caused by windage can be inversely deduced based on the monitored ground wire induced currents. The monitoring method and effect based on the induced potentials of the ground wires are similar to those based on the ground wire induced currents.

Furthermore, for the conductor offset situation caused by windage, an alarm may be generated by determining whether the conductor offset is greater than the preset offset threshold.

### Implementation 4

The following introduction describes an online monitoring method for the dynamic changes in positions of transmission line conductors based on electromagnetic signals of ground wires under the situation of conductor galloping.

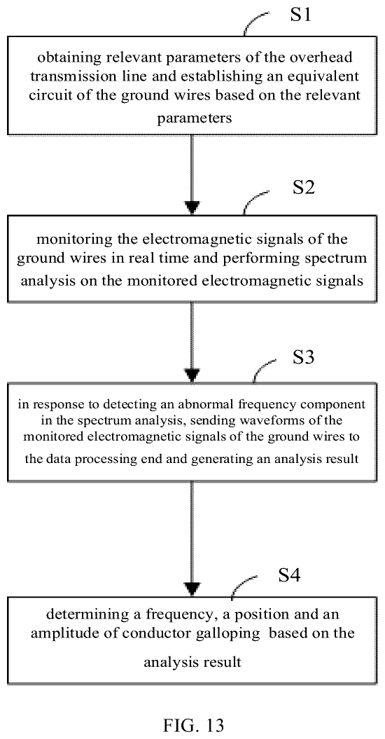

A flowchart illustrating the method for monitoring and locating conductor galloping based on the electromagnetic signals of the ground wires is provided in this embodiment. As shown in FIG. 13, the method includes the following steps.

At step 1, relevant parameters of the overhead transmission line are obtained, and an equivalent circuit of the ground wires is established based on the relevant parameters.

In this embodiment, the relevant parameters of the overhead transmission line include heights of the ground wires and the conductors, a span, and types of the ground wires and the conductors, etc. Based on the equivalent circuit of the ground wires, a phase decrease law and an amplitude decrease law of the galloping-related frequency component in the electromagnetic signals of the ground wires along the transmission line can be obtained, which facilitates the subsequent galloping features deducing and galloping span locating.

At step 2, the electromagnetic signals of the ground wires are monitored in real time and spectrum analysis is performed on the monitored electromagnetic signals.

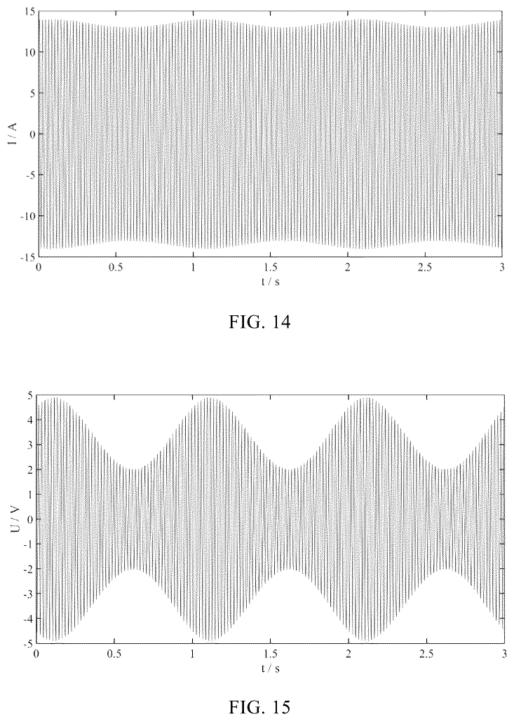

In this embodiment, the electromagnetic signals of the ground wires may include induced potentials of insulators in the segmented insulated ground wire or induced currents of an OPGW grounded tower by tower. When the conductors gallop, the vertical positions of the conductors will change periodically, further resulting in a periodical change of the mutual inductances between the conductors and the ground wires. Therefore, the ground wire induced potentials or the ground wire induced currents will change accordingly when the conductor currents are constant, as shown in FIG. 14 and FIG. 15.

The induced currents on the OPGW can be monitored by installing current transformers on the ground wire. Alternatively, the voltages of insulators in the segmented insulated ground wire can be detected by voltage sensors. That is, the ground wire induced currents or ground wire induced potentials can be detected in real time by arranging the voltage or current monitoring devices on the overhead ground wire, as shown in FIG. 3. Then the spectrum analysis is performed on the monitored ground wire induced potentials or ground wire induced currents.

At step 3, in response to detecting an abnormal frequency component in the spectrum analysis, waveforms of the monitored electromagnetic signals of the ground wires are sent to the data processing end, and an analysis result is generated.

In this embodiment, the abnormal frequency component in the electromagnetic signals of the ground wires means that a galloping-related frequency component is coupled to the ground wire induced potentials or the ground wire induced currents through the changing mutual inductances between the ground wires and the conductors. The galloping-related frequency component mentioned here is an additional low-frequency component coupled to the power-frequency electromagnetic signals of the ground wires when the vertical position of the conductor changes periodically.

When there is no abnormal frequency component in the monitored signals, monitoring the electromagnetic signals of the ground wires in real time is continued.

At step 4, a frequency, a position and an amplitude of the conductor galloping are determined based on the analysis result.

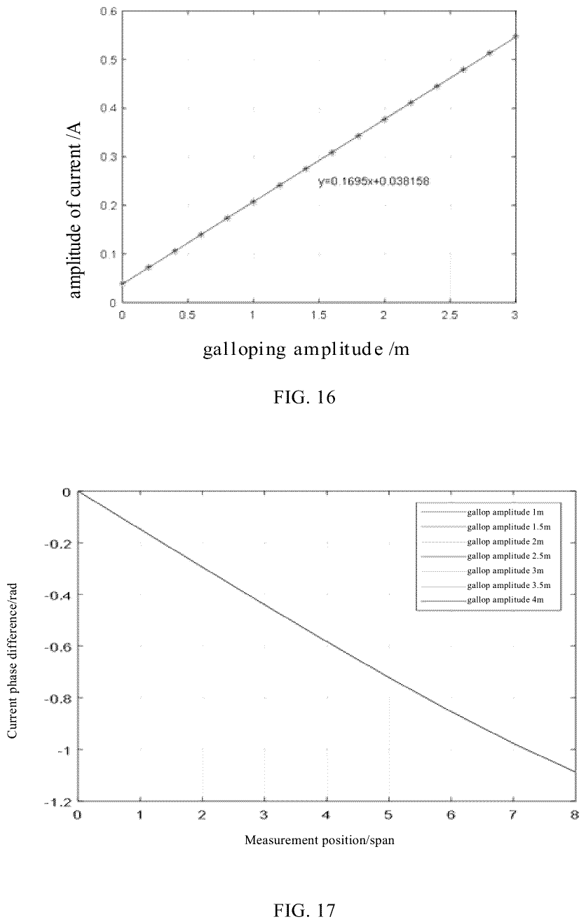

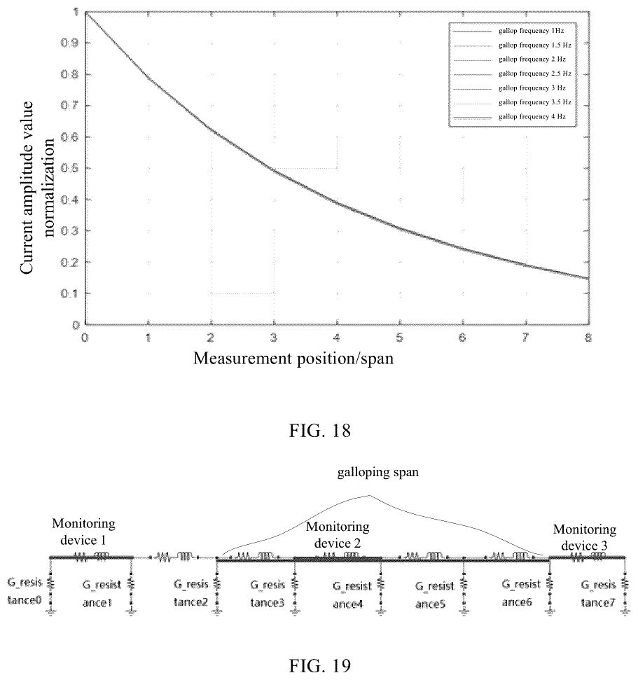

In this embodiment, the frequency of the conductor galloping can be obtained according to step 3. During the conductor galloping, the frequency of the conductor position change can be coupled to the electromagnetic signals of the ground wires through mutual inductances. As shown in FIG. 16, it can be seen that an amplitude of the galloping-related frequency component presents a linear relationship with an amplitude of the conductor galloping. When the conductor current is constant, a relationship between an amplitude of a galloping-related frequency component and an amplitude of conductor galloping can be established. More specifically, the galloping-related frequency component can also be monitored outside the galloping span. The connection method of the ground wires corresponding to FIG. 17 is that the normal ground wire is segmented insulated and the OPGW is grounded tower by tower. As shown in FIG. 17, the phase of the galloping-related frequency component induced on the OPGW current decreases approximately linearly along the transmission line. Therefore, the monitoring devices can be arranged in a distributed manner according to the above feature, and the position of the conductor galloping can be determined by the subsequent algorithm, which is based on the phase information monitored by the distributed devices along the transmission line and the phase distribution law of the galloping-related frequency component along the transmission line. As shown in FIG. 18, the amplitude of galloping-related frequency component decays in an exponential law along the transmission line. For a fixed transmission line, a parameter in an exponential decay expression is fixed. After obtaining the position of the conductor galloping through related algorithm, the amplitude of the conductor galloping at the galloping span can be inversely deduced based on the amplitude distribution law of the galloping-related frequency component along the transmission line in combination with the electromagnetic signals of the ground wires monitored by the distributed monitoring devices as well as the number of spans between the galloping span and each monitoring device.

In detail, determining the frequency, the position and the amplitude of the conductor galloping based on the analysis result includes the following steps.

Step 41, the frequency of the conductor galloping is determined. When the conductor is galloping, there will be abnormal frequency components with 50±f_{c} Hz in the ground wire electromagnetic signals, where f_{c} is the galloping frequency of the conductor. The frequency and the amplitude of the galloping-related frequency component in the ground wire induced currents or the ground wire induced potentials can be calculated by the matched data processing and communication modules when the abnormal frequency component is detected in the electromagnetic signals of the ground wires. Based on the obtained abnormal frequency component in the electromagnetic signals of the ground wires, the frequency of the conductor galloping can be calculated.

Step 42, phase information of the galloping-related frequency component in the electromagnetic signals of the ground wires is obtained. In an example, the phase information of the galloping-related frequency component may be obtained by performing spectrum analysis on waveforms of the electromagnetic signals of the ground wires.

Step 43, the position of the conductor galloping is determined based on the phase information of the galloping-related frequency component. In an example, the position of the conductor galloping is determined based on the phase information of the galloping-related frequency component monitored by the distributed monitoring devices and a phase distribution law of the galloping-related frequency component along the transmission line. An example of the ground wire connection in this embodiment is that the normal ground wire is segmented insulated and the OPGW is grounded tower by tower. The phase of the galloping-related frequency component superimposed on the ground wire induced currents or the ground wire induced potentials decreases approximately linearly when propagating along the transmission line. Therefore, the monitoring devices can be arranged in a distributed manner according to the above feature, and the position of the conductor galloping can be determined based on the subsequent algorithm.

Step 44, the amplitude of the conductor galloping is calculated based on the position of the conductor galloping and the monitored electromagnetic signals of the ground wires. More specifically, the amplitude of the conductor galloping may be calculated based on the position of the conductor galloping and amplitudes of the galloping-related frequency component monitored by the distributed monitoring devices, an amplitude distribution law of the galloping-related frequency component along the transmission line, as well as a relationship between the amplitude of the conductor galloping and the amplitude of the galloping-related frequency component. As shown in FIG. 18, the amplitude of the galloping-related frequency component in the ground wire exponentially decays along the transmission line. For a fixed transmission line, the parameter in the exponential decay expression is fixed, and the amplitude of the conductor galloping can be determined based on the mathematical expression after the position of the conductor galloping is obtained.

In this embodiment, determining the position of the conductor galloping based on the phase information of the galloping-related frequency component includes: determining a position of a device that monitors a maximum galloping-related frequency component; comparing a phase of the monitored maximum galloping-related frequency component with phases of the galloping-related frequency component monitored by the neighboring devices; and determining the position of the conductor galloping based on the phase distribution law of the galloping-related frequency component along the transmission line obtained from the ground wire equivalent circuit. The specific steps are listed as follows:

Step 51, the position of the device that monitors the maximum galloping-related frequency component in the ground wires is determined. In this embodiment, the position of the device that monitors the maximum galloping-related frequency component is the position closest to the position of the conductor galloping.

Step 52, the phase of the monitored maximum galloping-related frequency component is compared with the phases of the galloping-related frequency component monitored by the neighboring devices.

Step 53, the position of the conductor galloping is determined based on the phase distribution law of the galloping-related frequency component along the transmission line obtained by the ground wire equivalent circuit and a compared result obtained from the step 52.

The connection method of the ground wires corresponding to FIG. 17 is that the normal ground wire is segmented insulated and the OPGW is grounded tower by tower. As shown in FIG. 17, the phase of galloping-related frequency component induced on the ground wire induced currents or the ground wire induced potentials decreases approximately linearly along the transmission line. Therefore, the monitoring devices can be arranged in a distributed manner according to the above feature, and the position of the conductor galloping can be determined based on the subsequent algorithm.

In practical applications, the monitoring devices are installed every three spans. In this case, when the phase of the galloping-related component obtained by one monitoring device is the same as the phase of the galloping-related component obtained by another adjacent monitoring device, it indicates that the galloping occurs in the middle of the two monitoring devices. When the phase of the galloping-related component obtained by a certain monitoring device has a same difference with phases of the galloping-related component monitored by two neighboring monitoring devices, it indicates that the galloping occurs in the span where the certain monitoring device is located. It is noted that, the disclosure is not limited to installing one monitoring device every three spans, in other cases, the determination of the position of the conductor galloping is adjusted accordingly.

FIG. 19 is a schematic diagram illustrating a method of locating galloping spans for multi-span galloping situations proposed by an embodiment of the disclosure. In the following illustration, k is defined as a lag value of the phase at each span when the galloping-related frequency component propagates along the transmission line.

As shown in FIG. 19, monitoring devices are installed every three spans. For example, when a phase difference of the galloping-related frequency component monitored by monitoring devices 1 and 2 is between 2k and 3k, it may be determined that the one end of the multi-span conductor galloping is the third span. Similarly, when a phase difference of galloping-related frequency component monitored by monitoring devices 3 and 2 is between 1k and 2k, it may be determined that the other end of the multi-span conductor galloping is at the sixth span. In this way, the multi-span conductor galloping interval may be determined, for example, the third to sixth spans as shown in FIG. 19.

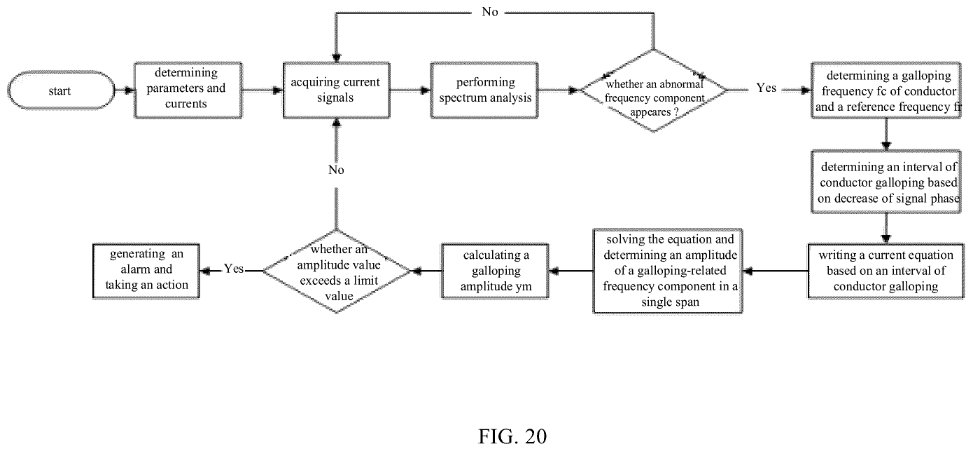

FIG. 20 is a schematic diagram illustrating an algorithm of conductor galloping locating for an overhead transmission line based on electromagnetic signals of ground wires according to an embodiment of the disclosure. As shown in FIG. 20, the ground wire induced potentials or ground wire induced currents are monitored in real time by distributed voltage monitoring devices or current monitoring devices on the ground wires, in combination with matched data processing and communication modules. When the ground wire induced potentials or ground wire induced currents are coupled with the galloping-related frequency component, waveforms of the monitored electromagnetic signals of the ground wires are sent to the data processing end. The interval of the conductor galloping, the frequency and the amplitude of the conductor galloping are determined according to a galloping identification and locating algorithm. An alarm is generated when the calculated amplitude of the conductor galloping is greater than an amplitude threshold. In this embodiment, the position of the conductor galloping is determined based on the position of the device that monitors the maximum galloping-related frequency component and the detected results of the distributed monitoring devices along the transmission line, which can realize locating of the conductor galloping without installing the monitoring devices span by span, significantly reduces the cost of monitoring and locating for the conductor galloping.

In order to implement the above embodiments, the disclosure also provides a non-transitory computer readable storage medium which has a computer program stored thereon. When the computer program is executed by a processor, the method of the above embodiments is implemented.

Embodiments of the present disclosure provide an online monitoring apparatus for dynamic changes in positions of transmission line conductors based on electromagnetic signals of ground wires. The apparatus includes: a processor; and a memory, configured to store a computer program executable by the processor. When the computer program is executed by the processor, the processor is caused to execute: monitoring electromagnetic signals of ground wires in real time by distributed voltage monitoring devices or current monitoring devices on the ground wires of an overhead transmission line in combination with matched data processing and communication modules, in which the electromagnetic signals of the ground wires are represented by ground wire induced potentials or ground wire induced currents; in response to changing in the electromagnetic signals, sending waveforms of the electromagnetic signals of the ground wires before and after changing to a data processing end, so as to determine change situations of the electromagnetic signals of the ground wires; deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and obtaining dynamic changes in positions and movement statuses of the transmission line conductors based on the position change situations of the conductors.

According to the apparatus of embodiments of the present disclosure, the ground wire induced potentials or ground wire induced currents are monitored in real time by the distributed voltage monitoring devices or current monitoring devices on the ground wires of the overhead transmission line in combination with the matched data processing and communication modules. In response to the changing in the ground wire induced potentials or the ground wire induced currents, the waveforms of the ground wire induced potentials or the ground wire induced currents before and after changing are sent to the data processing end. The change situations of the mutual inductances of the ground wires with the conductors are obtained based on the values of the conductor currents and the change situations of the acquired electromagnetic signals of the ground wires, and the position change situations of the conductors are obtained based on the change situations of the mutual inductances between the ground wires and the conductors. The dynamic changes in positions and the movement statuses of the transmission line conductors are online monitored based on the position change situations of the conductors. Therefore, the problems of large sensor number, unsatisfactory monitoring effect, high cost, difficult installation and maintenance in the existing methods may be solved. Additionally, the problems of a complex calculation principle and affecting normal operation of the transmission line in case of sensor failures in the existing methods may also be solved. Meanwhile, the method provided in the present disclosure can realize self-powered online monitoring of the conductor position information without additional power supply because the amplitudes of ground wire potential and current are stable and relatively large. The present disclosure provides the online monitoring apparatus for the dynamic changes in positions of the overhead transmission line conductors based on induced potentials of respective segmented insulated ground wire insulators or induced currents of an optical fiber composite overhead ground wire (OPGW) that is grounded tower by tower, which has advantages of simple principle, low cost, easy installation and maintenance, and high feasibility.

Reference throughout this specification to “an embodiment,” “some embodiments,” “an example,” “a specific example,” or “some examples,” means that a particular feature, structure, material, or characteristic described in combination with the embodiment or example is included in at least one embodiment or example of the disclosure. The appearances of the above phrases in various places throughout this specification are not necessarily referring to the same embodiment or example of the disclosure. Furthermore, the particular features, structures, materials, or characteristics may be combined in any suitable manner in one or more embodiments or examples. In addition, different embodiments or examples and features of different embodiments or examples described in the specification may be combined by those skilled in the art without mutual contradiction.

In addition, terms such as “first” and “second” are used herein for purposes of description and are not intended to indicate or imply the relative importance or implicitly specify the number of technical features indicated. Therefore, the feature defined with “first” and “second” may explicitly or implicitly include at least one such feature. In the description of the disclosure, “a plurality of” means at least two, for example, two or three, unless specified otherwise.

Any process or method described in a flowchart or described herein in other ways may be understood to include one or more modules, or portions of codes of executable instructions for achieving specific logical functions or steps in the process, the scope of a preferred embodiment of the disclosure includes other implementations, and functions may be performed in a substantially simultaneous order or a reverse order in addition to the order shown or discussed depending on the function involved, which should be understood by those skilled in the art.

The logic and/or step described in other manners herein or shown in the flowchart, for example, a particular sequence table of executable instructions for realizing the logical function, may be specifically achieved in any computer readable medium to be used by the instruction execution system, device or equipment (such as the system based on computers, the system comprising processors or other systems capable of obtaining the instruction from the instruction execution system, device and equipment and executing the instruction), or to be used in combination with the instruction execution system, device and equipment. As to the specification, “the computer readable medium” may be any device adaptive for including, storing, communicating, propagating or transferring programs to be used by or in combination with the instruction execution system, device or equipment. More specific examples of the computer readable medium include but are not limited to: an electronic connection (an electronic device) with one or more wires, a portable computer enclosure (a magnetic device), a Random Access Memory (RAM), a Read Only Memory (ROM), an Erasable Programmable Read-Only Memory (EPROM or a flash memory), an optical fiber device and a portable Compact Disk Read-Only Memory (CDROM). In addition, the computer readable medium may even be a paper or other appropriate medium capable of printing programs thereon, this is because, for example, the paper or other appropriate medium may be optically scanned and then edited, decrypted or processed with other appropriate methods when necessary to obtain the programs in an electric manner, and then the programs may be stored in the computer memories.

It should be understood that each part of the disclosure may be realized by the hardware, software, firmware or their combination. In the above embodiments, a plurality of steps or methods may be realized by the software or firmware stored in the memory and executed by the appropriate instruction execution system. For example, if it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a Programmable Gate Array (PGA), a Field Programmable Gate Array (FPGA), etc.

It would be understood by those skilled in the art that all or a part of the steps carried by the method in the above-described embodiments may be completed by relevant hardware instructed by a program. The program may be stored in a computer readable storage medium. When the program is executed, one step or a combination of the steps of the method in the above-described embodiments may be completed.

In addition, individual functional units in the embodiments of the disclosure may be integrated in one processing module or may be physically separated, or two or more units may be integrated in one module. The integrated module as described above may be achieved in the form of hardware, or may be achieved in the form of a software functional module. If the integrated module is achieved in the form of a software functional module and sold or used as a separate product, the integrated module may also be stored in a computer readable storage medium.

The storage medium mentioned above may be ROMs, magnetic disks or CD, etc. Although explanatory embodiments have been shown and described, it would be appreciated by those skilled in the art that the above embodiments are exemplary and are not to be construed as limiting the disclosure, and changes, modifications, alternatives, and modifications can be made in the embodiments without departing from scope of the disclosure.

What is claimed is:

1. An online monitoring method for dynamic changes in positions of transmission line conductors based on electromagnetic signals of ground wires, comprising:
monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents;
in response to changing in the electromagnetic signals, sending waveforms of the electromagnetic signals of the ground wires before and after changing to a data processing end, so as to determine change situations of the electromagnetic signals of the ground wires;
deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and
obtaining dynamic changes in positions and movement statuses of the transmission line conductors based on the position change situations of the conductors.

2. The method of claim 1, wherein a position change situation of a conductor comprises at least one of:
a conductor sag change situation, a conductor galloping situation and a conductor offset situation caused by windage.

3. The method of claim 2, wherein a cause of the conductor sag change situation comprises at least one of dynamic increase in transmission capacity of transmission line and conductor ice-over.

4. The method of claim 3, wherein when the cause of the conductor sag change situation is the dynamic increase in transmission capacity of transmission line or the conductor ice-over, obtaining the conductor sag change situation comprises:
analyzing and determining the change situations of the mutual inductances between the ground wires and the conductors based on change situations of the conductor currents and the change situations of the ground wire induced potentials or the ground wire induced currents;
obtaining change situations of distances between the ground wires and the conductors based on the change situations of the mutual inductances between the ground wires and the conductors; and
obtaining the conductor sag change situation based on the change situations of the distances between the ground wires and the conductors.

5. The method of claim 4, wherein obtaining the conductor sag change situation further comprises:
generating an alarm in response to determining that a conductor sag is greater than a preset sag threshold based on the conductor sag change situation.

6. The method of claim 4, wherein when the cause of the conductor sag change situation is the conductor ice-over, the method further comprises:
on the basis of considering of conductor deformation, obtaining a relationship between a conductor sag and thickness of ice covering the conductor by analyzing an influence of an ice gravity on a ratio of a conductor load per unit length to a cross-sectional area of the conductor, a horizontal stress of the conductor, and the conductor sag;
determining a conductor sag based on the conductor sag change situation; and
determining the thickness of ice covering the conductor according to the conductor sag and the relationship between the conductor sag and the thickness of ice covering the conductor.

7. The method of claim 2, wherein obtaining the conductor offset situation caused by windage comprises:
analyzing and determining the change situations of the mutual inductances between the ground wires and the conductors based on change situations of the conductor currents and the change situations of the ground wire induced potentials or the ground wire induced currents;
obtaining change situations of distances between the ground wires and the conductors based on the change situations of the mutual inductances between the ground wires and the conductors;
obtaining a spatial position change situation of each conductor based on the change situations of the distances between the ground wires and the conductors; and
obtaining the conductor offset situation caused by windage based on the spatial position change situation of the conductor.

8. The method of claim 7, further comprising:
generating an alarm in response to determining that a conductor offset is greater than a preset offset threshold.

9. The method of claim 2, further comprising: online monitoring and locating the conductor galloping situation, wherein online monitoring and locating the conductor galloping situation comprises:
step S1: obtaining relevant parameters of the overhead transmission line and establishing an equivalent circuit of the ground wires based on the relevant parameters;
step S2: monitoring the electromagnetic signals of the ground wires in real time and performing spectrum analysis on the monitored electromagnetic signals;
step S3: in response to detecting an abnormal frequency component in the spectrum analysis, sending waveforms of the monitored electromagnetic signals of the ground wires to the data processing end and generating an analysis result; and
step S4: determining a frequency, a position and an amplitude of conductor galloping based on the analysis result.

10. The method of claim 9, wherein online monitoring and locating the conductor galloping situation comprising:
step S5: executing steps S2, S3, and S4 repeatedly and continuously, and generating an alarm in response to the calculated amplitude of the conductor galloping being greater than a preset amplitude threshold.

11. The method of claim 9, wherein determining the frequency, the position and the amplitude of the conductor galloping based on the analysis result comprises:
determining the frequency of the conductor galloping by performing the spectrum analysis on the monitored electromagnetic signals of the ground wires;
obtaining phase information of a galloping-related frequency component in the electromagnetic signals of the ground wires;
determining the position of the conductor galloping based on the phase information of the galloping-related frequency component monitored by the distributed monitoring devices and a phase distribution law of the galloping-related frequency component along the transmission line; and
calculating the amplitude of the conductor galloping based on the position of the conductor galloping and amplitudes of the galloping-related frequency component monitored by the distributed monitoring devices, an amplitude distribution law of the galloping-related frequency component along the transmission line, and a relationship between the amplitude of the conductor galloping and the amplitude of the galloping-related frequency component.

12. The method of claim 1, further comprising:
supplying power to the monitoring devices through the ground wire induced potentials or the ground wire induced currents to achieve self-power.

13. A non-transitory computer readable storage medium having a computer program stored thereon, wherein when the computer program is executed by a processor, an online monitoring method for dynamic changes in positions of transmission line conductors based on electromagnetic signals of ground wires is implemented, in which, the method comprises:
monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents;
in response to changing in the electromagnetic signals, sending waveforms of the electromagnetic signals of the ground wires before and after changing to a data processing end, so as to determine change situations of the electromagnetic signals of the ground wires;
deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and
obtaining dynamic changes in positions and movement statuses of the transmission line conductors based on the position change situations of the conductors.

14. The storage medium of claim 13, wherein a position change situation of a conductor comprises at least one of:
a conductor sag change situation, a conductor galloping situation and a conductor offset situation caused by windage.

15. The storage medium of claim 14, wherein a cause of the conductor sag change situation comprises at least one of: dynamic increase in transmission capacity of transmission line, and conductor ice-over.

16. The storage medium of claim 15, wherein when the cause of the conductor sag change situation is the dynamic increase in transmission capacity of transmission line or the conductor ice-over, obtaining the conductor sag change situation comprises:
analyzing and determining the change situations of the mutual inductances between the ground wires and the conductors based on change situations of the conductor currents and the change situations of the ground wire induced potentials or the ground wire induced currents;
obtaining change situations of distances between the ground wires and the conductors based on the change situations of the mutual inductances between the ground wires and the conductors; and
obtaining the conductor sag change situation based on the change situations of the distances between the ground wires and the conductors; and
generating an alarm in response to determining that a conductor sag is greater than a preset sag threshold based on the conductor sag change situation.

17. The storage medium of claim 16, wherein when the cause of the sag change situation is conductor ice-over, the method further comprises:
on the basis of considering of conductor deformation, obtaining a relationship between horizontal stress and thickness of ice covering a conductor and a relationship between a conductor sag and thickness of ice covering a conductor by analyzing an influence of an ice gravity on a ratio of a conductor load per unit length to a cross-sectional area of the conductor, the horizontal stress of the conductor and the conductor sag;
determining a conductor sag based on the conductor sag change situation; and
determining the thickness of ice covering the conductor according to the conductor sag and the relationship between the conductor sag and the thickness of ice covering the conductor.

18. The storage medium of claim 14, wherein obtaining the conductor offset situation caused by windage comprises:
analyzing and determining the change situations of the mutual inductances between the ground wires and the conductors based on change situations of the conductor currents and the change situations of the ground wire induced potentials or the ground wire induced currents;
obtaining change situations of distances between the ground wires and the conductors based on the change situations of the mutual inductances between the ground wires and the conductors;
obtaining a spatial position change situation of each conductor based on the change situations of the distances between the ground wires and the conductors;
obtaining the conductor offset situation caused by windage based on the spatial position change situation of the conductor; and
generating an alarm in response to determining that a conductor offset is greater than a preset offset threshold.

19. The storage medium of claim 14, wherein the method further comprises: online monitoring and locating the conductor galloping situation, wherein online monitoring and locating the conductor galloping situation comprises:
step S1: obtaining relevant parameters of the overhead transmission line and establishing an equivalent circuit of the ground wires based on the relevant parameters;
step S2: monitoring the electromagnetic signals of the ground wires in real time and performing spectrum analysis on the monitored electromagnetic signals;
step S3: in response to detecting an abnormal frequency component in the spectrum analysis, sending waveforms of the monitored electromagnetic signals of the ground wires to the data processing end and generating an analysis result;
step S4: determining a frequency, a position and an amplitude of the conductor galloping based on the analysis result; and
step S5: executing steps S2, S3, and S4 repeatedly and continuously, and generating an alarm in response to the calculated amplitude of the conductor galloping being greater than a preset amplitude threshold.

20. An online monitoring apparatus for dynamic changes in positions of transmission line conductors based on electromagnetic signals of ground wires, comprising:
a processor; and
a memory, configured to store a computer program executable by the processor;
wherein, when the computer program is executed by the processor, the processor is caused to execute:
monitoring electromagnetic signals of ground wires in real time by distributed voltage monitoring devices or current monitoring devices on the ground wires of an overhead transmission line in combination with matched data processing and communication modules, wherein the electromagnetic signals of the ground wires are represented by ground wire induced potentials or ground wire induced currents;
in response to changing in the electromagnetic signals, sending waveforms of the electromagnetic signals of the ground wires before and after changing to a data processing end, so as to determine change situations of the electromagnetic signals of the ground wires;
deducing change situations of mutual inductances between the ground wires and conductors based on values of conductor currents and the change situations of the electromagnetic signals of the ground wires, and further deducing position change situations of the conductors based on the change situations of the mutual inductances between the ground wires and the conductors; and
obtaining dynamic changes in positions and movement statuses of the transmission line conductors based on the position change situations of the conductors.
